(19) United States
(12) Patent Application Publication
(10) Pub. No.: US 2025/0248147 A1
(43) Pub. Date: Jul. 31, 2025

(54) IMAGE SENSOR

(71) Applicant: Samsung Electronics Co., Ltd., Suwon-si (KR)

(72) Inventors: DAEHYUNG LEE, Suwon-si (KR); YOUNGWOO CHUNG, Suwon-si (KR); Yongmin YANG, Suwon-si (KR)

(21) Appl. No.: 18/978,683

(22) Filed: Dec. 12, 2024

(30) Foreign Application Priority Data
Jan. 26, 2024 (KR) 10-2024-0012137

(51) Int. Cl. H10F 39/00; H10F 39/12; H10F 39/18

(52) U.S. Cl. CPC H10F 39/80373; H10F 39/014; H10F 39/182; H10F 39/199; H10F 39/8063; H10F 39/807; H10F 39/811

(57) ABSTRACT

An image sensor includes a substrate including a first pixel region, a separation structure provided in the substrate to define the first pixel region, and a source follower transistor on the first pixel region. The source follower transistor includes a source follower gate electrode and a first gate insulating layer interposed between the source follower gate electrode and the substrate, the source follower gate electrode extends in a first direction and is disposed between a device isolation pattern and the separation structure. The first gate insulating layer includes a first portion adjacent to the device isolation pattern, and a second portion adjacent to the separation structure. The first portion includes a first sidewall adjacent to the device isolation pattern, the first portion has a first thickness in a vertical direction, and the first thickness decreases as a distance from the first sidewall increases in the first direction.

### CROSS-REFERENCE TO RELATED APPLICATIONS

This U.S. non-provisional patent application claims priority under 35 U.S.C. § 119 to Korean Patent Application No. 10-2024-0012137 filed on Jan. 26, 2024, in the Korean Intellectual Property Office, the entire content of which is hereby incorporated by reference.

### BACKGROUND

Aspects of the inventive concept relate to an image sensor, and more specifically relate to an image sensor with improved electrical and optical characteristics.

An image sensor is a device that converts optical images into electrical signals. With increased development of the computer and communications industries, there may be an increased demand for high performance image sensors that may be used for capturing images in a variety of applications such as digital cameras, camcorders, personal communication systems (PCS), gaming machines, security cameras, micro-cameras for medical applications, and/or robots.

Image sensors may include complementary metal-oxide-semiconductor (CMOS) image sensors and charge coupled devices (CCD). The CMOS image sensors operate with a simple driving manner/way and may be integrated with signal processing circuits on a single chip, thus enabling products that include the CMOS image sensors to be scaled down. In addition, CMOS image sensors may operate with relatively low power consumption. Thus, CMOS image sensors are applicable to portable electronic devices. Furthermore, CMOS image sensors may be fabricated using CMOS fabrication techniques, which may reduce manufacturing costs. Moreover, CMOS image sensors may provide high resolution images. Accordingly, the use of CMOS image sensors has increased.

### SUMMARY

An object of the inventive concept is to provide to an image sensor with improved electrical and optical characteristics.

An object of the inventive concept is to provide to a method of manufacturing an image sensor with improved electrical and optical characteristics.

The problem to be solved by the inventive concept is not limited to the problems mentioned above, and other problems not mentioned will be clearly understood by those skilled in the art from the description below.

An image sensor according to some embodiments of the inventive concept includes a substrate including a first pixel region, a separation structure provided in the substrate to define the first pixel region, and a source follower transistor on the first pixel region, wherein the source follower transistor includes a source follower gate electrode and a first gate insulating layer interposed between the source follower gate electrode and the substrate, the source follower gate electrode extends in a first direction and is disposed a device isolation pattern and the separation structure, the first gate insulating layer includes a first portion adjacent to the device isolation pattern, including a first sidewall adjacent to the device isolation pattern and a second portion adjacent to the separation structure, the first portion has a first thickness in a vertical direction, and the first thickness decreases as a distance from the first sidewall increases in the first direction.

An image sensor according to some embodiments of the inventive concept includes a substrate including a first pixel region and a source follower transistor on the first pixel region, wherein the source follower transistor includes a first source/drain pattern, a second source/drain pattern, a source follower gate electrode, and a source follower gate insulating layer interposed between the source follower gate electrode and the substrate, the source follower gate electrode is interposed between the first source/drain pattern and the second source/drain pattern and extends in a first direction, the source follower gate insulating layer includes a first edge portion adjacent to the first source/drain pattern, a second edge portion spaced apart from the first edge portion in a second direction, the second direction intersecting the first direction, and a central portion interposed between the first edge portion and the second edge portion, and the first edge portion has a thickness greater than that of the central portion, and the second edge portion has a thickness greater than that of the central portion.

An image sensor according to some embodiments of the inventive concept includes a substrate including a pixel region, the substrate having first and second surfaces facing each other, a separation structure provided in the substrate to define the pixel region, a photoelectric conversion region provided in the substrate in the pixel region, a floating diffusion region provided in the substrate and spaced apart from the photoelectric conversion region in the pixel region, a device isolation layer extending from the first surface into the substrate and defining a first active region and a second active region on the pixel region, the first active region being adjacent to the floating diffusion region, the second active region being adjacent to the separation structure, a transfer gate electrode disposed on the first surface in the first active region and extending into the substrate, a source follower gate electrode disposed on the first surface in the second active region, a source follower gate insulating layer disposed between the source follower gate electrode and the first surface, a first source/drain pattern provided in the substrate in the pixel region at one side of the source follower gate electrode, a second source/drain pattern provided in the substrate in the pixel region on the other side of the source follower gate electrode, a gate insulating layer between the source follower gate electrode and the substrate, a microlens on the second surface, the microlens overlapping the photoelectric conversion region, and a wiring layer disposed on the first surface, wherein the source follower gate electrode is provided between the device isolation pattern and the separation structure and extends in a first direction, the source follower gate insulating layer includes a first portion adjacent to the device isolation pattern, the first portion including a first sidewall adjacent to the device isolation pattern and a second portion adjacent to the separation structure, the first portion has a first thickness in a vertical direction, and the first thickness decreases as a distance from the first sidewall increases in the first direction.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram of an image sensor according to embodiments of the inventive concept.

FIG. 2 is a circuit diagram of a unit pixel of an image sensor according to embodiments of the inventive concept.

FIG. 3A is a plan view of an image sensor according to embodiments of the inventive concept.

FIG. 3B is a plan view of an image sensor according to embodiments of the inventive concept, and is an enlarged view of region ‘M’ of FIG. 3A.

FIG. 4A is a cross-sectional view of an image sensor according to embodiments of the inventive concept, taken along line A-A′ of FIG. 3A.

FIG. 4B is a cross-sectional view of an image sensor according to embodiments of the inventive concept, and is an enlarged view of region ‘N’ of FIG. 4A.

FIG. 5 is a plan view of an image sensor according to another embodiment of the inventive concept, and is an enlarged view of region ‘M’ in FIG. 4A.

FIG. 6A is a top view of an image sensor according to another embodiment of the inventive concept.

FIG. 6B is a cross-sectional view of an image sensor according to another embodiment of the inventive concept, taken along line B-B′ of FIG. 6A.

FIGS. 7 and 8 are plan views of image sensors according to different embodiments of the inventive concept, respectively.

FIGS. 9-11, 12A, 12B, and 13 are diagrams for explaining a method of manufacturing an image sensor according to an embodiment of the inventive concept.

FIG. 14 is a schematic plan view of an image sensor including a semiconductor device according to embodiments of the inventive concept.

FIGS. 15 and 16 are cross-sectional views of an image sensor according to embodiments of the inventive concept, taken along line C-C′ of FIG. 14.

### DETAILED DESCRIPTION

Hereinafter, embodiments of the inventive concept will be described in detail with reference to the attached drawings.

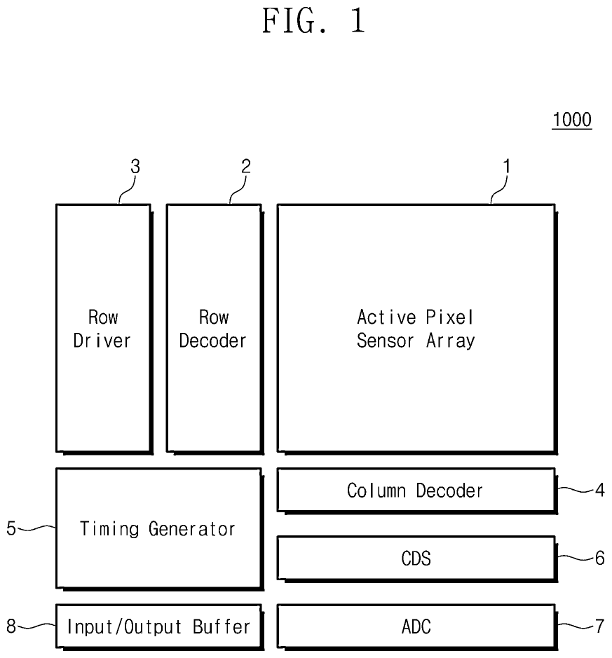

FIG. 1 is a block diagram of an image sensor according to an embodiment of the inventive concept.

Referring to FIG. 1, an image sensor 1000 includes an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. The correlated double sampler 6 is provided with the converted electrical signals.

The row driver 3 provides the active pixel sensor array 1 with several of the driving signals for driving several unit pixels in accordance with a decoded result obtained from the row decoder 2. When the unit pixels are arranged in a matrix shape, the driving signals may be provided for respective rows.

The timing generator 5 provides timing and control signals to the row decoder 2 and the column decoder 4.

The correlated double sampler 6 receives the electrical signals generated from the active pixel sensor array 1, and holds and samples the received electrical signals. The correlated double sampler 6 may perform a double sampling operation to sample a specific noise level and a signal level of the electrical signal, and outputs a difference level corresponding to a difference between the noise and signal levels.

The analog-to-digital converter 7 converts analog signals, which correspond to the difference level received from the correlated double sampler 6, into digital signals, and outputs the converted digital signals.

The input/output buffer 8 latches the digital signals and then sequentially outputs the latched digital signals to an image signal processing unit (not shown) in response to the decoded result obtained from the column decoder 4.

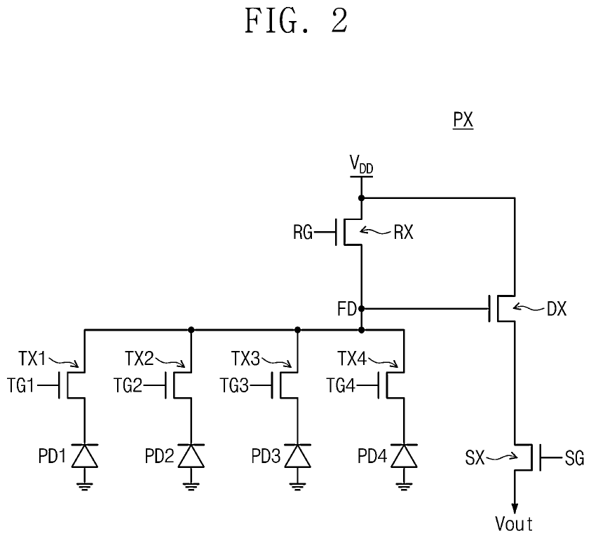

FIG. 2 is a circuit diagram of a unit pixel of an image sensor according to embodiments of the inventive concept.

Referring to FIGS. 1 and 2, the active pixel sensor array 1 may include a plurality of unit pixels PX, which may be arranged in a matrix shape. Each of the unit pixels PX may include a first photoelectric conversion element PD1, a second photoelectric conversion element PD2, a third photoelectric conversion element PD3, a fourth photoelectric conversion element PD4, a first transfer transistor TX1, a second transfer transistor TX2, a third transfer transistor TX3, a fourth transfer transistor TX4, and logic transistors RX, SX, and DX.

The logic transistors RX, SX, and DX may include a reset transistor RX, a selection transistor SX, and a drive transistor DX. The first transfer transistor TX1, the second transfer transistor TX2, the third transfer transistor TX3, the fourth transfer transistor TX4, the reset transistor RX, and the selection transistor SX may include a first transfer gate electrode TG1, a second transfer gate electrode TG2, a third transfer gate electrode TG3, a fourth transfer gate electrode TG4, a reset gate RG, and a selection gate SG, respectively. Each of the pixels PX may further include a floating diffusion region FD.

The floating diffusion region FD may receive charges generated in the first to fourth photoelectric conversion elements PD1, PD2, PD3, and PD4 and store the charges cumulatively. The drive transistor DX may be controlled depending on the amount of photocharges accumulated in the floating diffusion region FD.

The reset transistor RX may periodically reset charges accumulated in the floating diffusion region FD. A drain electrode of the reset transistor RX may be connected to the floating diffusion region FD, and a source electrode of the reset transistor RX may be connected to a power supply voltage VDD. When the reset transistor RX is turned on, the power supply voltage VDD connected to the source electrode of the reset transistor RX may be applied to the floating diffusion region FD. Accordingly, when the reset transistor RX is turned on, charges accumulated in the floating diffusion region FD may be discharged and the floating diffusion region FD may be reset.

The drive transistor DX may function as a source follower buffer amplifier. The drive transistor DX may amplify potential charge in the floating diffusion region FD and output the potential charge to an output line Vout.

The selection transistor SX may select the pixels PX to be read row by row. When the selection transistor SX is turned on, the power supply voltage VDD may be applied to a drain electrode of the drive transistor DX.

FIG. 2 illustrates a unit pixel PX having four photoelectric conversion elements PD1, PD2, PD3, and PD4 and seven transistors TX1, TX2, TX3, TX4, RX, DX, and SX, but the image sensor according to the inventive concept is not limited thereto. For example, the reset transistor RX, the drive transistor DX, or the selection transistor SX may be shared by neighboring pixels PX. Accordingly, integration of the image sensor may be improved.

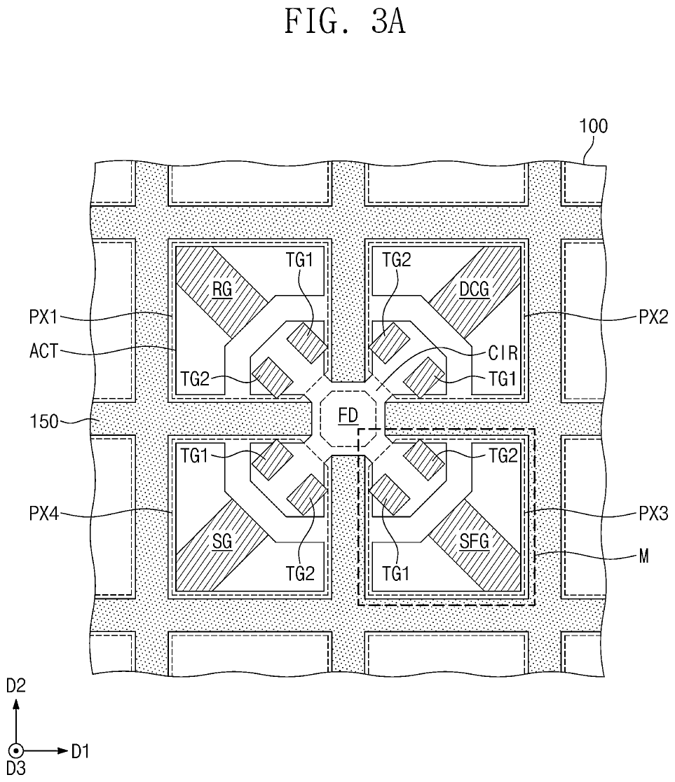

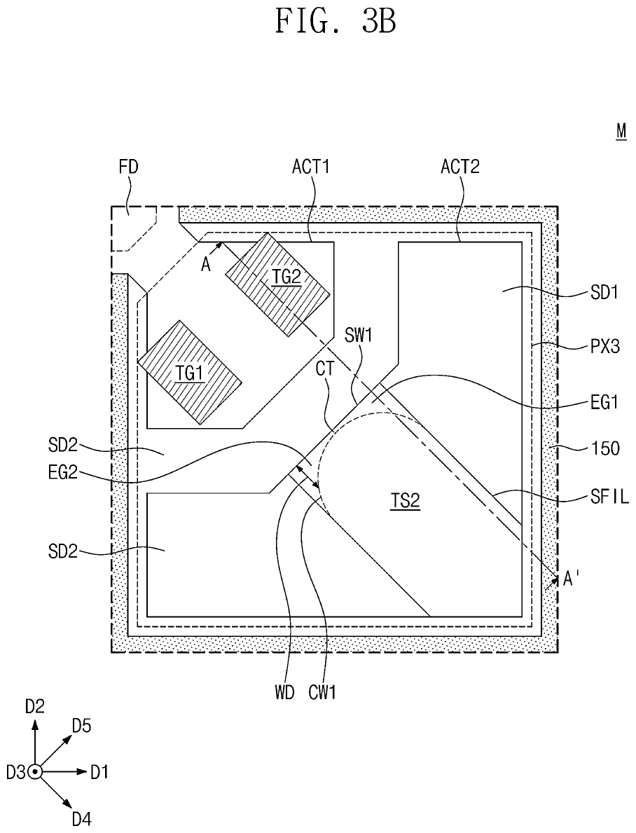

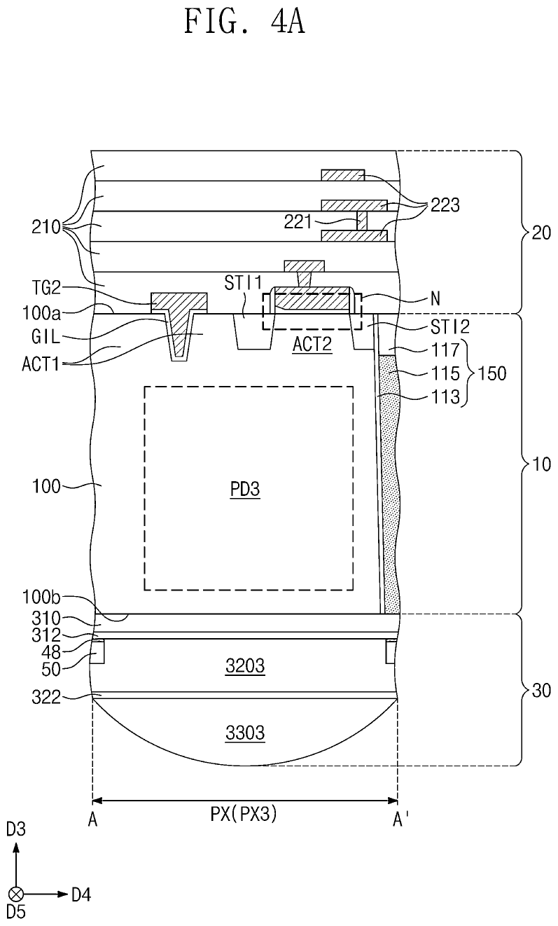

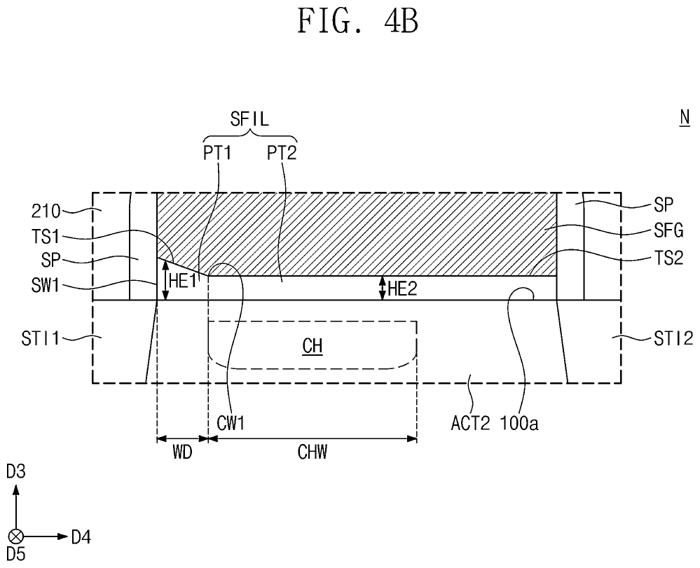

FIG. 3A is a plan view of an image sensor according to embodiments of the inventive concept. FIG. 3B is a plan view of an image sensor according to embodiments of the inventive concept, and is an enlarged view of region ‘M’ of FIG. 3A. FIG. 4A is a cross-sectional view of an image sensor according to embodiments of the inventive concept, taken along line A-A′ of FIG. 3A. FIG. 4B is a cross-sectional view of an image sensor according to embodiments of the inventive concept, and is an enlarged view of region ‘N’ of FIG. 4A.

Referring to FIGS. 3A and 4A, an image sensor according to embodiments of the inventive concept may include a photoelectric conversion layer 10, a wiring layer 20, and a light-transmitting layer 30. The photoelectric conversion layer 10 may be disposed between the wiring layer 20 and the light-transmitting layer 30.

The photoelectric conversion layer 10 may include a substrate 100, and the substrate 100 may include a plurality of pixel regions PX. The substrate 100 may be a semiconductor substrate (e.g., a silicon substrate, a germanium substrate, a silicon-germanium substrate, a group II/VI compound semiconductor substrate, or a group III/V compound semiconductor substrate) or a silicon on insulator (SOI) substrate. The substrate 100 may have a first surface 100a and a second surface 100b facing each other. The plurality of pixel regions PX may be two-dimensionally arranged in a first direction D1 and a second direction D2 parallel to the first surface 100a of the substrate 100. The first direction D1 and the second direction D2 may intersect each other.

The photoelectric conversion layer 10 may further include a separation structure 150 that penetrates the substrate 100 and is disposed between the plurality of pixel regions PX. The separation structure 150 may penetrate the substrate 100 in a third direction D3 perpendicular to the first surface 100a of the substrate 100. The separation structure 150 may extend from the first surface 100a of the substrate 100 toward the second surface 100b of the substrate 100.

An upper surface of the separation structure 150 may be substantially coplanar with the first surface 100a of the substrate 100, and a lower surface of the separation structure 150 may be substantially coplanar with the second surface 100b of the substrate 100. The separation structure 150 may prevent cross-talk between neighboring pixel regions PX.

Photoelectric conversion regions PD may be disposed in each pixel region PX of the substrate 100. In one embodiment, a first photoelectric conversion region PD1 may be disposed in a first pixel region PX1, and a second photoelectric conversion region PD2 may be disposed in a second pixel region PX2. The first pixel region PX1 and the second pixel region PX2 may be adjacent to each other in the first direction D1. The first photoelectric conversion region PD1 and the second photoelectric conversion region PD2 may be adjacent to each other in the first direction D1. A third pixel region PX3 may be arranged to be spaced apart from the second pixel region PX2 in the second direction D2. A fourth pixel region PX4 may be arranged to be spaced apart from the third pixel region PX3 in the first direction D1. The third photoelectric conversion region PD3 may be dispose in a third pixel region PX3, and the fourth photoelectric conversion region PD4 may be disposed in a fourth pixel region PX4. The first to fourth photoelectric conversion regions PD1, PD2, PD3, and PD4 are shown as being arranged in a clockwise direction, but this is only for convenience of explanation and the inventive concept is not limited thereto.

Gate electrodes may be provided on each of the first to fourth pixel regions PX1, PX2, PX3, and PX4. For example, the gate electrodes may include one of a reset gate electrode RG, a selection gate electrode SG, a source follower gate electrode SFG, and a double conversion gain gate electrode DCG.

A separation structure 150 may be disposed between the first photoelectric conversion region PD1 and the second photoelectric conversion region PD2. The separation structure 150 may extend in the second direction D2 between the first photoelectric conversion region PD1 and the second photoelectric conversion region PD2. The same may also apply between the second photoelectric conversion region PD2 and the third photoelectric conversion region PD3 and between the third photoelectric conversion region PD3 and the fourth photoelectric conversion region PD4. Light incident from the outside may be converted into an electrical signal in the photoelectric conversion regions PD1, PD2, PD3, and PD4.

A device isolation pattern STI may be disposed adjacent to the first surface 100a of the substrate 100. The device isolation pattern STI may define active regions ACT on the first surface 100a of the substrate 100 in each of the pixel regions PX. For example, the device isolation pattern STI may include at least one of a silicon oxide layer, a silicon nitride layer, and a silicon oxynitride layer. The active regions ACT may be spaced apart from each other in each of the pixel regions PX and may have different sizes. The device isolation pattern STI may be interposed between the active regions ACT.

A first active region ACT1 and a second active region ACT2 may be defined on the pixel region PX by the device isolation pattern STI. The first active region ACT1 may be adjacent to the second and fourth photoelectric conversion regions PD2 and PD4. The first active region ACT1 and the second active region ACT2 may be spaced apart from each other in a fourth direction D4. The fourth direction D4 may be a direction between the first direction D1 and the second direction D2.

The separation structure 150 may include a liner insulating pattern 113, a semiconductor pattern 115, and a capping insulating pattern 117. The semiconductor pattern 115 may penetrate at least a portion of the substrate 100 in the third direction D3. The liner insulating pattern 113 may be provided between the semiconductor pattern 115 and the substrate 100. The capping insulating pattern 117 may be provided on the semiconductor pattern 115.

A lower surface of the semiconductor pattern 115 may be positioned at substantially the same level as the second surface 100b of the substrate 100. The upper surface of the semiconductor pattern 115 may be in contact with a lower surface of the capping insulating pattern 117. An air gap or void may exist inside the semiconductor pattern 115. It should be appreciated that an “air gap” may comprise a gap having air or other gases (e.g., such as those present during manufacturing) or may comprise a gap forming a vacuum therein. The semiconductor pattern 115 may include, for example, polysilicon. The semiconductor pattern 115 may include a semiconductor material doped with impurities. The impurity may have a P-type or N-type conductivity type. As an example, the semiconductor pattern 115 may include boron-doped polycrystalline silicon. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The substrate 100 may have a first conductivity type, and the first and second photoelectric conversion regions PD1 and PD2 may be regions doped with impurities of a second conductivity type different from the first conductivity type. For example, the first conductivity type and the second conductivity type may be P-type and N-type, respectively. In this case, the second conductivity type impurities may include N-type impurities such as phosphorus, arsenic, bismuth, and/or antimony. Each of the first and second photoelectric conversion regions PD1 and PD2 may form a PN junction with the substrate 100 to form a photodiode. According to some embodiments, the semiconductor pattern 115 of the separation structure 150 may include a semiconductor material doped with an impurity of the first conductivity type (e.g., a P-type impurity).

A lower surface of the capping insulating pattern 117 may be positioned at a lower level than a lower surface of the device isolation pattern STI, or may be positioned at the same level. The lower surface of the capping insulating pattern 117 may have a rounded shape. An upper surface of the capping insulating pattern 117 may be positioned at substantially the same level as an upper surface of the device isolation pattern STI (i.e., the first surface 100a of the substrate 100).

The liner insulating pattern 113 may cover a sidewall of the semiconductor pattern 115 and a sidewall of the capping insulating pattern 117 conformally (i.e., with a substantially uniform thickness). The liner insulating pattern 113 and the capping insulating pattern 117 may include, for example, at least one of silicon oxide, silicon oxynitride, and silicon nitride.

A first transfer gate electrode TG1 and the floating diffusion region FD may be disposed on each pixel region PX and adjacent to the first surface 100a of the substrate 100. The first transfer gate electrode TG1 may be disposed on the first active region ACT1. The first transfer gate electrode TG1 may overlap the first photoelectric conversion region PD1 vertically (e.g., in the third direction D3). The same may apply to the second to fourth photoelectric conversion regions PD2 to PD4.

The first transfer gate electrode TG1 may extend from the first surface 100a of the substrate 100 toward the inside of the substrate 100 (i.e., toward the second surface 100b of the substrate 100). An arrangement of the first transfer gate electrode TG1 may not be limited thereto.

First and second transfer gate electrodes TG1 and TG2 may be provided in the first active region ACT1 of the third pixel region PX3. The first and second transfer gate electrodes TG1 and TG2 may extend into the substrate 100. At least a portion of the first transfer gate electrode TG1 may be provided in a vertical trench recessed from the first surface 100a of the substrate 100. The first transfer gate electrode TG1 may include a lower portion inserted into the substrate 100 and an upper portion connected to the lower portion and protruding above the first surface 100a of the substrate 100.

The lower portion of the first transfer gate electrode TG1 may penetrate at least a portion of the substrate 100. The lower portions of each of the first and second transfer gate electrodes TG1 and TG2 may extend into the substrate 100 toward the first photoelectric conversion region PD1. An upper surface of each of the electrodes TG1 and TG2 may protrude above an upper surface of the corresponding active region ACT (i.e., the first surface 100a of the substrate 100).

A lower surface of the first transfer gate electrode TG1 may be positioned at a lower level than the first surface 100a of the substrate 100. For example, the lower surface of the first transfer gate electrode TG1 may be positioned at a lower level than the lower surface of the device isolation pattern STI. In other words, the lower surface of the device isolation pattern STI may be closer to the first surface 100a of the substrate 100 than the lower surface of the first transfer gate electrode TG1. First and second transfer gate insulating layers GIL may be interposed between each of the first and second transfer gate electrodes TG1 and TG2 and the substrate 100.

The photoelectric conversion layer 10 may further include a floating diffusion region FD disposed in the pixel region PX of the substrate 100. One floating diffusion region FD may be provided to correspond to the plurality of photoelectric conversion regions PD1, PD2, PD3, and PD4. The floating diffusion region FD may be provided to overlap the first to fourth photoelectric conversion regions PD1, PD2, PD3, and PD4.

The first to fourth pixel regions PX1, PX2, PX3, and PX4 adjacent to each other may form a pixel group. One floating diffusion region FD may be provided at a center of the pixel group. The first to fourth pixel regions PX1, PX2, PX3, and PX4 may share the one floating diffusion region FD.

The separation structure 150 may extend between the first photoelectric conversion region PD1 and the second photoelectric conversion region PD2 of the substrate that do not overlap the floating diffusion region FD. The same may also apply between the second photoelectric conversion region PD2 and the third photoelectric conversion region PD3 and between the third photoelectric conversion region PD3 and the fourth photoelectric conversion region PD4. The separation structure 150 may not extend between the first and third photoelectric conversion regions PD1 and PD3 of the substrate that overlap the floating diffusion region FD. The same may be apply between the second photoelectric conversion region PD2 and the fourth photoelectric conversion region PD4.

A central intervening region CIR may be defined between the first and third photoelectric conversion regions PD1 and PD3 of the substrate that overlap the floating diffusion region FD. The floating diffusion region FD may overlap the central intervening region CIR. The central intervening region CIR may include a material different from the doping material of the first photoelectric conversion region PD1 and the third photoelectric conversion region PD3. The central intervening region CIR may be, for example, a DTI center cut (DCC) region.

The first and second transfer gate electrodes TG1 and TG2 may be disposed adjacent to the floating diffusion region FD. The floating diffusion region FD may be regions doped with impurities (e.g., N-type impurities) of the second conductivity type different from the first conductivity type of the substrate 100.

A first source/drain pattern SD1 and a second source/drain pattern SD2 may be provided on the second active region ACT2. A source follower gate electrode SFG may be provided between the first source/drain pattern SD1 and the second source/drain pattern SD2.

The source follower gate electrode SFG may extend in the fourth direction D4.

The wiring layer 20 may include wiring (e.g., MOS transistors) connected to the photoelectric conversion layer 10. An electrical signal converted in the photoelectric conversion layer 10 may be processed in the wiring layer 20.

The wiring layer 20 may be disposed on the first surface 100a of the substrate 100. The wiring layer 20 may include interlayer insulating layers 210 sequentially stacked on the first surface 100a of the substrate 100. The interlayer insulating layer 210 may be disposed on the first surface 100a of the substrate 100 and cover the first transfer gate electrode TG1. The interlayer insulating layers 210 may include an insulating material. The interlayer insulating layers 210 may include, for example, at least one of silicon oxide, silicon oxynitride, and silicon nitride.

The wiring layer 20 may further include wiring structures 221 and 223 provided in the interlayer insulating layer 210. The wiring structures 221 and 223 may include metal wirings 223 and contact plugs 221 connecting the metal wirings 223. Some of the contact plugs 221 may be connected to the floating diffusion region FD. The metal wirings 223 and the contact plugs 221 may include a conductive material.

The light-transmitting layer 30 may be provided on the second surface 100b of the substrate 100. The light-transmitting layer 30 may include a flat insulating layer 310, a protective layer 312, light blocking patterns 48, low refractive patterns 50, color filters 3201 and 3203, and microlenses 3301 and 3303.

The flat insulating layer 310 may be interposed between the second surface 100b of the substrate 100 and the color filters 3201 and 3203. The flat insulating layer 310 may include a plurality of insulating layers having different refractive indices, and each of the insulating layers may include a transparent insulating material. The insulating layers may have high transmittance with an appropriate thickness. In one embodiment, the flat insulating layer 310 may be a single layer or a composite layer including at least one of a metal oxide layer or a metal fluoride layer each containing an amount of oxygen or fluorine less than the stoichiometric ratio, or a combination thereof. Accordingly, the flat insulating layer 310 may have a negative fixed charge and function as a fixed charge layer. As an example, the flat insulating layer 310 may include a metal oxide layer or metal fluoride layer including at least one of hafnium (Hf), zirconium (Zr), aluminum (Al), tantalum (Ta), titanium (Ti), yttrium (Y), or lanthanide, or a combination thereof. The flat insulating layer 310 may improve dark current and white spots.

The protective layer 312 may be stacked on the flat insulating layer 310. The protective layer 312 may include at least one of silicon oxide (SiO), silicon carbonate (SiOC), silicon nitride (SiN), or a combination thereof.

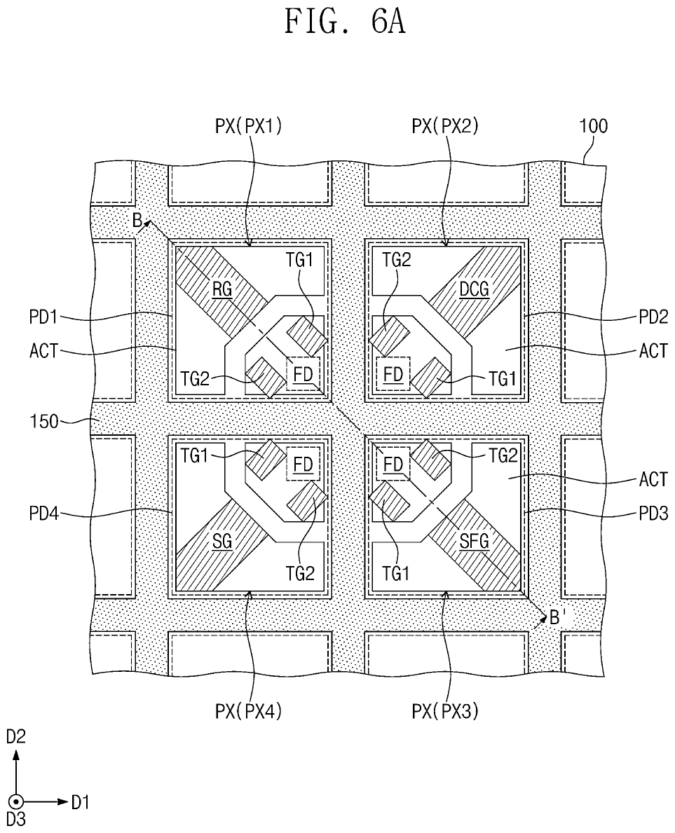

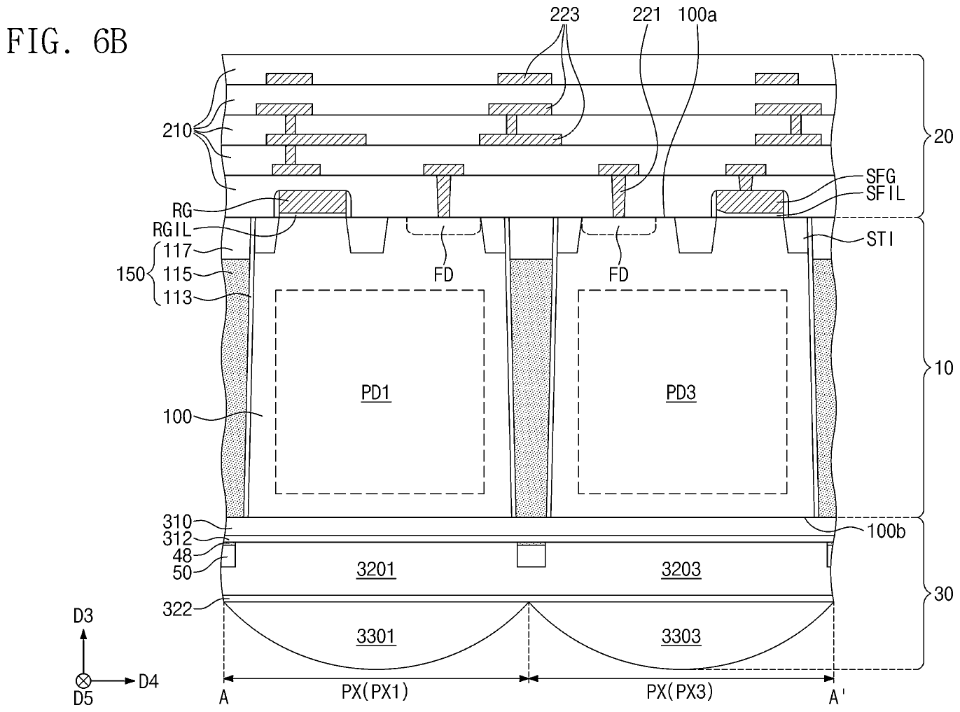

Light blocking patterns 48 may be disposed on the protective layer 312. Low refractive patterns 50 may be respectively disposed on the light blocking patterns 48. The light blocking pattern 48 and the low refractive pattern 50 overlap the separation structure 150 and may have a two-dimensional grid shape. The light blocking pattern 48 may include titanium, for example. The low refractive patterns 50 have the same thickness and may include the same organic materials. The low refractive pattern 50 may have a smaller refractive index than that of the color filters 3201 and 3203, which will be described later with respect to FIG. 6A. For example, the low refractive pattern 50 may have a refractive index of about 1.3 or less. The light blocking pattern 48 and the low refractive pattern 50 may prevent crosstalk between adjacent unit pixels PX.

Color filters corresponding to each of the first to second pixel regions PX1, PX2, PX3, and PX4 may be provided. As an example, a color filter 3201 corresponding to the first pixel region PX1 may be provided in the first pixel region PX1. The same may apply to the second to fourth pixel regions PX2, PX3, and PX4.

The color filters 3201 and 3203 may be disposed between the low refractive patterns 50. The color filters 3201 and 3203 may each have one color among blue, green, and red. As another example, the color filters 3201 and 3203 may include other colors such as cyan, magenta, or yellow. In the image sensor according to this example, the color filters 3201 and 3203 may be arranged in a Bayer pattern. In another example, the color filters 3201 and 3203 may be arranged in a 2×2 array of tetra patterns, 3×3 arrays of nona patterns, or 4×4 arrays of hexadeca patterns.

A lens insulating layer 322 may be interposed between the color filters 3201 and 3203 and the microlenses 3301 and 3303. Microlenses 3301 and 3303 may be disposed on the lens insulating layer 322. The microlenses 3301 and 3303 may overlap the corresponding photoelectric conversion regions PD1 and PD3. In one embodiment, the first microlens 3301 may overlap the first photoelectric conversion region PD1.

The cross-sectional views illustrate that the first photoelectric conversion region PD1 provided in the substrate 100 of the first pixel regions PX1 and the third photoelectric conversion region PD3 provided in the substrate 100 of the third pixel regions PX3, but features shown in the drawings and described in this specification may be equally applied to the second photoelectric conversion region PD2 and the fourth photoelectric conversion region PD4.

Referring to FIGS. 3B and 4B, the source follower gate electrode will be described in more detail.

Referring to FIGS. 3B and 4B, a source follower gate electrode SFG may be provided on the second active region ACT2 of the substrate 100. A source follower gate insulating layer SFIL may be interposed between the source follower gate electrode SFG and the first surface 100a of the substrate 100. Gate spacers SP may be provided on both sidewalls of the source follower gate electrode SFG. As another example, the gate spacer SP may be omitted. The source follower gate insulating layer SFIL may include an insulating material. For example, the source follower gate insulating layer SFIL may include at least one of silicon oxide, silicon oxynitride, and silicon nitride.

The device isolation pattern STI may include a first device isolation pattern STI1 and a second device isolation pattern STI2. The first device isolation pattern STI1 may be interposed between the first active region ACT1 and the second active region ACT2. The second device isolation pattern STI2 may be in contact with the separation structure 150. The second active region ACT2 may be disposed between the first device isolation pattern STI1 and the second device isolation pattern STI2.

The source follower gate insulating layer SFIL may include a first portion PT1 adjacent to the first device isolation pattern STI1 and a second portion PT2 adjacent to the separation structure 150. The second device isolation pattern STI2 may be disposed between second portion PT2 and the separation structure 150. The first portion PT1 and the second portion PT2 may be adjacent to each other in the fourth direction D4. The second portion PT2 may be closer to the separation structure 150 than the first portion PT1.

The first portion PT1 may include a first sidewall SW1 adjacent to the first device isolation pattern STI1. The first side wall SW1 may be spaced apart from the second portion PT2 in the fourth direction D4.

The first portion PT1 may include a first thickness HE1, which is a height in the vertical direction D3. The second portion PT2 may include a second thickness HE2, which is a height in the vertical direction D3. The first thickness HE1 of the first portion PT1 may be greater than the second thickness HE2 of the second portion PT2. The first thickness HE1 may decrease as a distance increases from the first side wall SW1 in the fourth direction D4 (i.e., a direction towards the second device isolation pattern STI2). The first thickness HE1 may have a maximum value at the first sidewall SW1.

A cross section of the first portion PT1 may have a trapezoidal profile. The first portion PT1 may include a first upper surface TS1 that is in contact with the source follower gate electrode SFG. The second portion PT2 may include a second upper surface TS2 that is in contact with the source follower gate electrode SFG. The first upper surface TS1 may have an inclined profile. The first upper surface TS1 may have an inclination, extend from the first side wall SW1 in the fourth direction D4, and be connected to the second upper surface TS2.

A first intersection line CW1 may be provided where the first upper surface TS1 and the second upper surface TS2 meet each other. When viewed in a two-dimensional perspective view, the first intersection line CW1 may have a curvature. For example, the first intersection line CW1 may have a semicircular profile.

Gate electrodes and gate insulating layers may be provided on the first, second, and fourth pixel regions PX1, PX2, and PX4 adjacent to the third pixel region PX3. For example, a reset gate insulating layer may be interposed between the reset gate electrode RG on the first pixel region PX1 and the substrate 100. The first thickness HE1 of the first portion PT1 may be greater than a thickness of the reset gate insulating layer. The first thickness HE1 of the first portion PT1 may be greater than a thickness of the first and second transfer gate insulating layers GIL.

A channel region CH may be provided on an upper portion of the second active region ACT2 in the substrate 100. The channel region CH may be formed below the second portion PT2. Because the first thickness HE1 of the first portion PT1 is greater than the second thickness HE2 of the second portion PT2, more current may flow under the second portion PT2 than under the first portion PT1. Accordingly, the channel region CH may be formed under the second portion PT2 instead of the first portion PT1. The channel region CH may be spaced apart from the first device isolation pattern STI1.

The channel region CH may have an effective width CHW in the fourth direction D4. Because no current flows under the first portion PT1, the channel region CHW may be spaced apart from the first device isolation pattern STI1 and the effective width CHW may increase. As a result, the area of the channel region CH may be expanded.

Referring to FIG. 3B, the first portion PT1 may include a first edge portion EG1, a second edge portion EG2, and a central portion CT. The first edge portion EG1 may be spaced apart from the second edge portion EG2 in a fifth direction D5. The fifth direction D5 may be between the first direction D1 and the second direction D2 and may be perpendicular to the fourth direction D4. The first edge portion EG1 may be adjacent to the first source/drain pattern SD1. The second edge portion EG2 may be adjacent to the second source/drain pattern SD2.

A thickness of the first edge portion EG1 may be greater than a thickness of the central portion CT. A thickness of the second edge portion EG2 may be greater than the thickness of the central portion CT. The first thickness HE1 of the first portion PT1 may decrease from the first edge portion EG1 toward the central portion CT and may have a minimum value at the central portion CT. Thereafter, the first thickness HE1 may increase again from the central portion CT toward the second edge portion EG2. The thickness of the first portion PT1 may decrease and then increase as the distance from the first edge portion EG1 increases in the fifth direction D5. The thickness of the first edge portion EG1 and the second edge portion EG2 may be greater than a thickness of the transfer gate insulating layer GIL. The thickness of the first edge portion EG1 and the second edge portion EG2 may be greater than the second thickness HE2.

The first portion PT1 may have a first width WD in the fourth direction D4. The first width WD may be defined as the shortest distance from the first side wall SW1 to the second portion PT2 in the fourth direction D4. The first width WD may decrease from the first edge portion EG1 to the central portion CT. The first width WD may increase from the central portion CT to the second edge portion EG2. The first width WD may have a minimum value at the central portion CT.

Referring to FIGS. 3A to 4B, in the image sensor according to aspects of the inventive concept, the source follower gate insulating layer SFIL may be interposed between the source follower gate electrode SFG and the second active region ACT2. The first portion PT1 of the source follower gate insulating layer SFIL may be thicker than the second portion PT2 of the source follower gate insulating layer SFIL. Accordingly, current may flow under the second portion PT2 having a smaller thickness, and a channel region CH may be formed under the second portion PT2 to be spaced apart from the first device isolation pattern STI1.

When viewed in a plan view, the first portion PT1 may include first and second source/drain patterns SD1 and SD2 and first and second edge portions EG1 and EG2 respectively. The thickness of the first and second edge portions EG1 and EG2 may be greater than the thickness of the central portion CT. As the first and second edge portions EG1 and EG2 become thicker, the channel region CH formed below the second portion PT2 may be spaced apart from the first device isolation pattern STI1. As a result, the width of the channel region CH may be increased and the reduction of noise may be improved. As a result, electrical characteristics of the image sensor may be improved.

Hereinafter, other embodiments of the inventive concept will be described in more detail. For convenience of explanation, description of the same contents as those described with reference to FIGS. 3A to 4B will be omitted and differences will be described in detail.

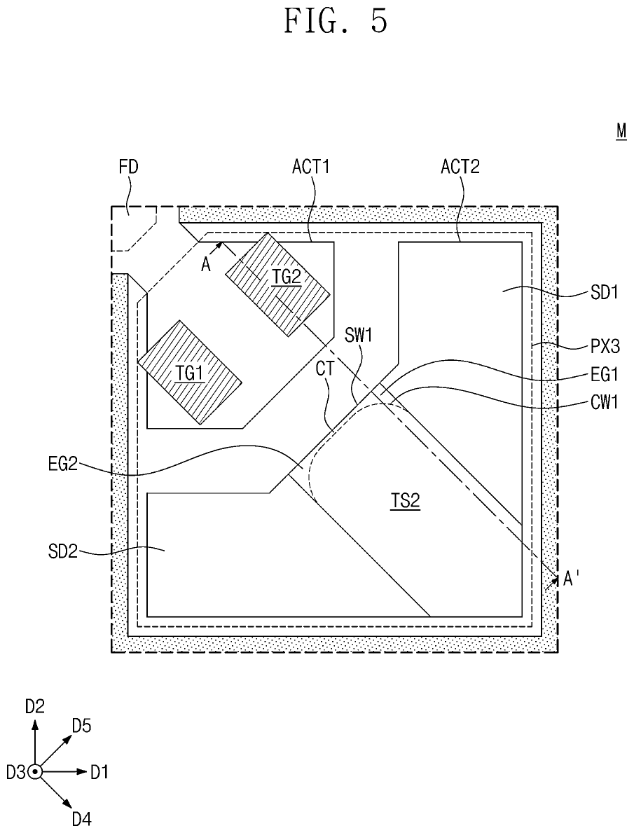

FIG. 5 is a plan view of an image sensor according to another embodiment of the inventive concept, and is an enlarged view of region ‘M’ in FIG. 4A. Referring to FIG. 5, at least a portion of the first intersection line CW1 may be a straight line. The first width WD of the first portion PT1 may decrease from the first edge portion EG1 to the central portion CT, may remain constant, and may increase from the central portion CT to the second edge portion EG2. As another example, the first width WD may have various values depending on the manufacturing process.

Referring to FIGS. 3B and 5, the thickness of the source follower gate insulating layer SFIL may increase in the first and second edge portions EG1 and EG2 adjacent to the first device isolation pattern STI1. Accordingly, portions of the channel region CH formed below the second portion PT2 adjacent to the first and second source/drain patterns SD1 and SD2 may be spaced apart from the first device isolation pattern STI1.

FIG. 6A is a top view of an image sensor according to another embodiment of the inventive concept. FIG. 6B is a cross-sectional view of an image sensor according to another embodiment of the inventive concept, taken along line B-B′ of FIG. 6A.

Referring to FIGS. 6A and 6B, the separation structure 150 may surround each of the plurality of pixel regions PX when viewed in a plan view. The separation structure 150 may define a plurality of pixel regions PX. The separation structure 150 may extend to surround each pixel region PX in the first direction D1 and the second direction D2.

Each of the floating diffusion regions FD may be arranged to overlap each of the corresponding first to fourth photoelectric conversion regions PD1, PD2, PD3, and PD4. For example, one photoelectric conversion region may overlap one floating diffusion region FD. The floating diffusion regions FD may be spaced apart from each other in the first direction D1 and the second direction D2 with the separation structure 150 interposed therebetween.

A reset gate insulating layer RGIL may be interposed between the reset gate electrode RG on the first pixel region PX1 and the substrate 100. The first thickness HE1 of the first portion PT1 may be greater than a thickness of the reset gate insulating layer.

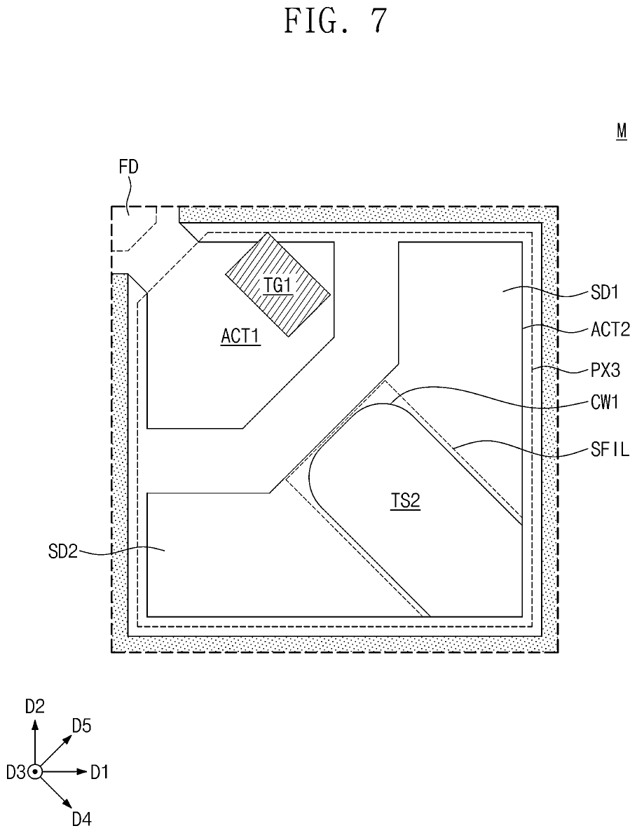

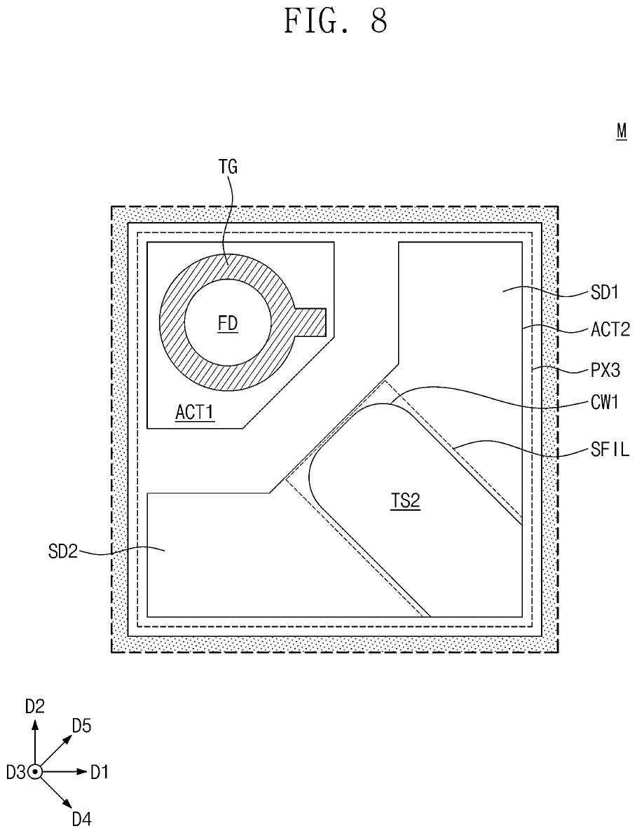

FIGS. 7 and 8 are plan views of image sensors according to different embodiments of the inventive concept, respectively.

Referring to FIG. 7, only one transfer gate electrode TG may be provided on the first active region ACT1. For example, either the first transfer gate electrode TG1 or the second transfer gate electrode TG2 may be provided. Although not shown, as shown in FIG. 6A, a separation structure 150 may surround each of the plurality of pixel regions PX.

Referring to FIG. 8, a floating diffusion region FD and a transfer gate electrode TG may be provided on the first active region ACT1. When viewed in a plan view, the transfer gate electrode TG may surround the floating diffusion region FD. The transfer gate electrode TG may have a ring shape. The transfer gate electrode TG may include a protrusion to be connected to the wiring layer 20.

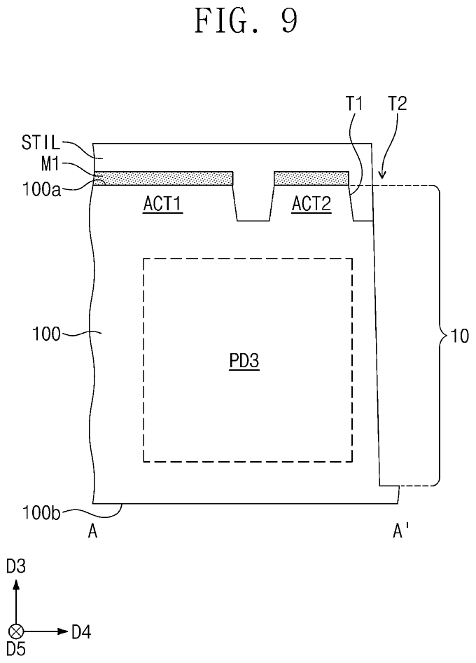

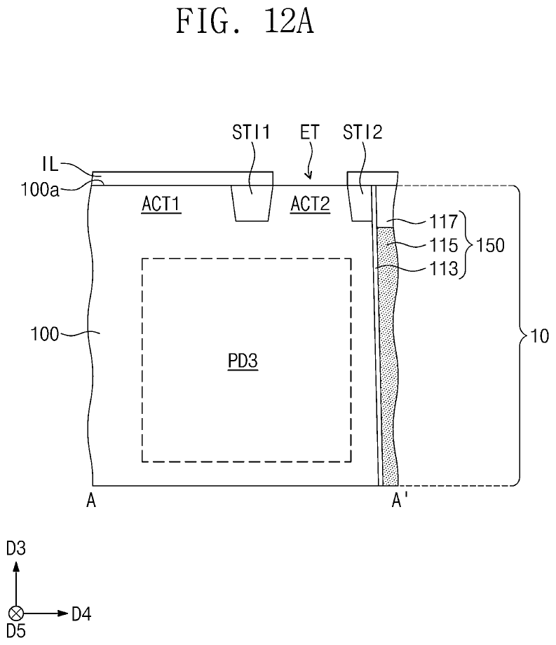

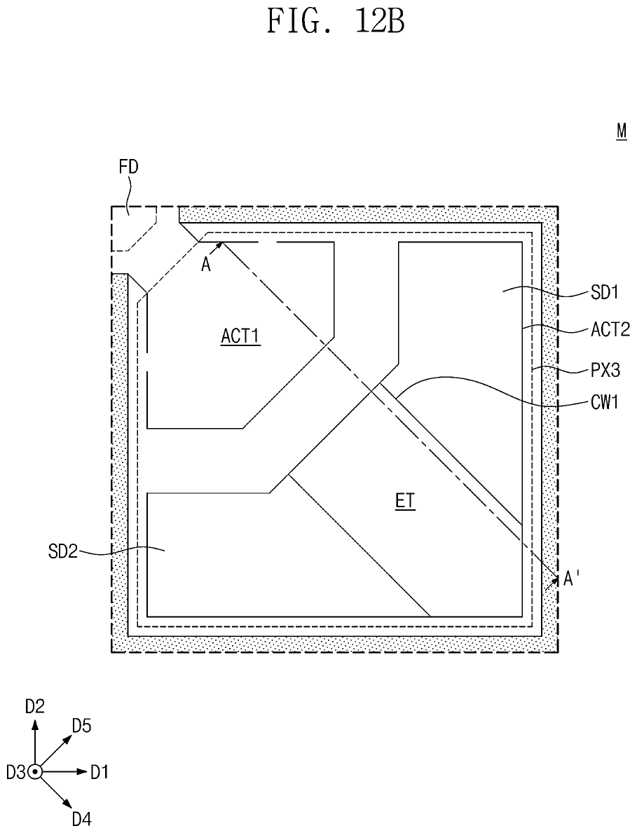

FIGS. 9 to 13 are diagrams for explaining a method of manufacturing an image sensor according to an embodiment of the inventive concept. FIGS. 9, 10, 11, 12A, and 13 are cross-sectional views corresponding to line A-A′ in FIG. 3B. FIG. 12B is an enlarged view of region ‘M’ in FIG. 3A.

Referring to FIG. 9, a substrate 100 having a first surface 100a and a second surface 100b facing each other may be provided. The substrate 100 may have a first conductivity type (e.g., P type). A first trench T1 may be formed adjacent to the first surface 100a of the substrate 100. Forming the first trench T1 may include forming a first mask pattern M1 on the first surface 100a of the substrate 100, and etching the substrate 100 using the first mask pattern M1 as a mask. The first trench T1 may define a first active region ACT1 and a second active region ACT2 in the substrate 100.

A device isolation layer STIL may be formed on the first surface 100a of the substrate 100. The device isolation layer STIL may cover the first mask pattern M1 and fill the first trench T1. For example, the device isolation layer STIL may include a silicon oxide layer, a silicon nitride layer, and/or a silicon oxynitride layer.

A second trench T2 may be formed in the substrate 100. Forming the second trench T2 involves forming a hard mask pattern on the device isolation layer STIL that defines the region where the second trench T2 will be formed, and etching the device isolation layer STIL and the substrate 100 using the hard mask pattern as a mask.

The second trench T2 may define a plurality of pixel regions PX in the substrate 100. The plurality of pixel regions PX may be arranged in the first direction D1 and the second direction D2. The second trench T2 may surround each pixel region PX when viewed in a plan view. The second trench T2 may extend to surround each pixel region PX in the first direction D1 and the second direction D2. Each of the plurality of pixel regions PX may include active regions ACT defined by the first trench T1. Referring to FIG. 9, the second trench T2 may extend into the pixel region PX.

Four pixel regions PX adjacent to each other may form a pixel group. The second trench T2 may not be formed in an region corresponding to a center of the pixel group.

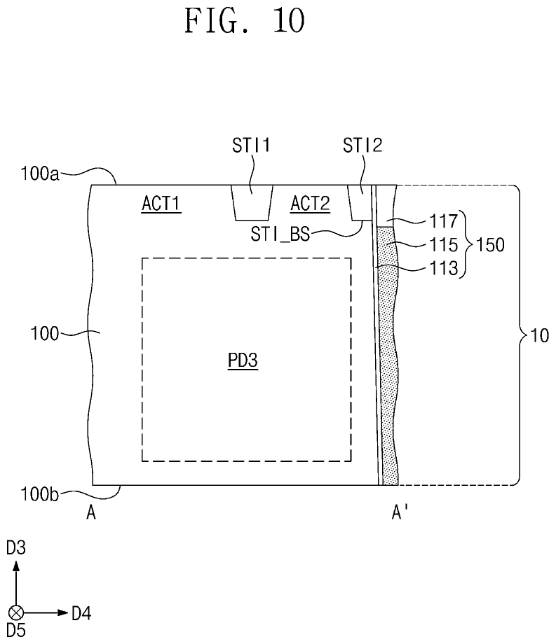

Referring to FIG. 10, an upper portion of the device isolation layer STIL and the first mask pattern M1 may be removed to form a device isolation pattern STI. The device isolation layer STIL may be removed leaving only the device isolation layer STIL positioned at a level lower than the first surface 100a of the substrate 100.

A separation structure 150 may be formed to fill the second trench T2. The separation structure 150 may include a liner insulation pattern 113 that conformally covers an inner wall of the second trench T2, a semiconductor pattern 115 filling a lower portion of the second trench T2, and a capping insulating pattern 117 provided on the semiconductor pattern 115 to fill the remainder of the second trench T2.

Forming the separation structure 150 may include, for example, forming a liner insulating layer that conformally covers the inner wall of the second trench T2, forming a semiconductor layer filling the second trench T2 on the liner insulating layer, etching back the semiconductor layer to form a semiconductor pattern 115, forming a capping insulating layer that fills the remainder of the second trench T2, and planarizing the capping insulating layer and liner insulating layer to form a liner insulating pattern 113 and a capping insulating pattern 117.

Forming the semiconductor pattern 115 may further include, for example, injecting a first conductivity type impurity (e.g., P-type impurity) into the semiconductor pattern 115. The planarization process for forming the liner insulating pattern 113 and the capping insulating pattern 117 may include planarizing the capping insulating layer and the liner insulating layer until the first surface 100a of the substrate 100 is exposed.

A first photoelectric conversion region PD1 and a second photoelectric conversion region PD2 may be formed in the pixel region PX. A third photoelectric conversion region PD3 and a fourth photoelectric conversion region PD4 may be formed in the pixel region PX.

The separation structure 150 may be interposed between the first photoelectric conversion region PD1 and the second photoelectric conversion region PD2. The separation structure 150 may be interposed between the second photoelectric conversion region PD2 and the third photoelectric conversion region PD3, and the third photoelectric conversion region PD3 and the fourth photoelectric conversion region PD4. The separation structure 150 may not be interposed between the first photoelectric conversion region PD1 and the third photoelectric conversion region PD3 or between the second photoelectric conversion region PD2 and the fourth photoelectric conversion region PD4.

For example, forming a plurality of photoelectric conversion regions PD1, PD2, PD3, and PD4 may include injecting impurities with a second conductivity type (e.g., N-type) different from the first conductivity type (e.g., P-type) in the substrate 100.

A thinning process may be performed on the second surface 100b of the substrate 100, and a portion of the substrate 100 and the separation structure 150 may be removed by the thinning process. For example, the thinning process may include grinding or polishing the second surface 100b of the substrate 100, and/or anisotropic and/or isotropic etching. A lower portion of the separation structure 150 may be removed through a thinning process, and a lower surface of the separation structure 150 may be substantially coplanar with the second surface 100b of the substrate 100.

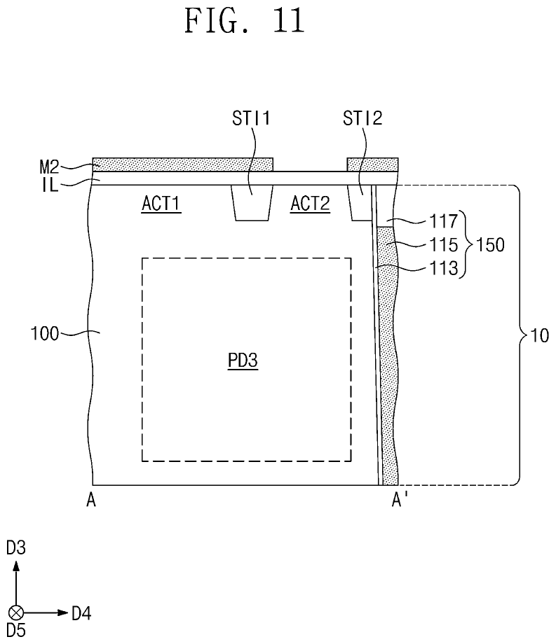

Referring to FIG. 11, a first insulating layer IL may be formed on the first surface 100a of the substrate 100. A second mask pattern M2 may be formed on the first insulating layer IL. The second mask pattern M2 may have an etch selectivity different from that of the first insulating layer IL. The second mask pattern M2 may define an region where a source follower gate electrode SFG will be formed.

Referring to FIGS. 12A and 12B, the first insulating layer IL may be etched using the second mask pattern M2 as a mask. The first insulating layer IL may be etched to form a first etch portion ET. The first surface 100a of the substrate 100 may be exposed on the first active region ACT1 by the first etch portion ET.

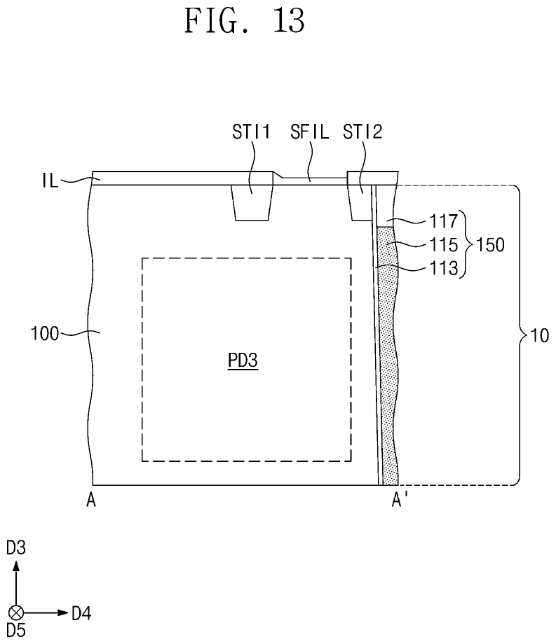

Referring to FIG. 13, a source follower gate insulating layer SFIL may be formed in the first etch portion ET. Forming the source follower gate insulating layer SFIL may include forming a second insulating layer on the first etch portion ET and etching an upper portion of the second insulating layer.

An etch rate of the second insulating layer may be variously changed depending on the fourth direction D4. Specifically, a portion adjacent to the second device isolation pattern STI2 may be etched more than a portion adjacent to the first device isolation pattern STI1. As a result, a first portion PT1 with a large thickness and a second portion PT2 with a small thickness may be formed. As another example, a portion of the second insulating layer adjacent to the first device isolation pattern STI1 may not be etched. The second insulating layer may include at least one of silicon oxide, silicon oxynitride, and silicon nitride.

The first portion PT1 may include an upper surface that is obliquely etched through the etching process. A level of an upper surface of the second portion PT2 may be lower than a level of an upper surface of the first insulating layer IL. The highest level of the upper surface of the first portion PT1 may be the same as a level of an upper surface of the first insulating layer IL.

Referring again to FIGS. 3A and 4A, the first transfer gate electrode TG1, the second transfer gate electrode TG2, and the floating diffusion region FD may be formed on each pixel region PX and may be formed adjacent to the first surface 100a of the substrate 100. The first transfer gate electrode TG1 and the second transfer gate electrode TG2 may be formed on the corresponding first active region ACT1.

The floating diffusion region FD may be formed at the center of a pixel group composed of a plurality of photoelectric conversion regions PD1, PD2, PD3, and PD4. For example, the floating diffusion region FD may be formed between the first photoelectric conversion region PD1 and the third photoelectric conversion region PD3 and between the second photoelectric conversion region PD2 and the fourth photoelectric conversion region PD4.

A lower portion of each of the first and second transfer gate electrodes TG1 and TG2 may extend into the interior of the substrate 100 through the first active region ACT1. An upper portion of each of the first and second transfer gate electrodes TG1 and TG2 may protrude above an upper surface of the first active region ACT1 (i.e., the first surface 100a of the substrate 100). The floating diffusion region FD may be formed by doping an impurity of a second conductivity type different from the first conductivity type of the substrate 100 (e.g., N-type impurity). A transfer gate insulating layer GIL may be formed between each of the first and second transfer gate electrodes TG1 and TG2 and the substrate 100.

Interlayer insulating layers 210 and wiring structures 221 and 223 may be formed on the first surface 100a of the substrate 100. The interlayer insulating layers 210 may cover transfer transistors and logic transistors. The interlayer insulating layers 210 may be formed of a material with excellent gap fill characteristics, and may be formed to have a flat top.

Contact plugs 221 connected to the floating diffusion region FD may be formed in the interlayer insulating layers 210. Metal wirings 223 may be formed between the interlayer insulating layers 210. The metal wirings 223 may be formed between the interlayer insulating layers 210. The contact plugs 221 and the metal wirings 223 may be formed of, for example, copper (Cu), aluminum (Al), tungsten (W), titanium (Ti), molybdenum (Mo), tantalum (Ta), and titanium nitride layers. (TiN), tantalum nitride (TaN), zirconium nitride (ZrN), tungsten nitride (WN), and alloys made of combinations thereof.

A flat insulating layer 310 and a protective layer 312 may be sequentially formed on the second surface 100b of the substrate 100. A color filter 320 (e.g., color filters 3201 and 3203) may be formed on the protective layer 312. The color filter 320 may include a plurality of color filters 320, and the plurality of color filters 320 may be respectively disposed on a plurality of pixel regions PX. Each of the plurality of color filters 320 may be vertically (e.g., in the third direction D3) overlap the first to fourth photoelectric conversion regions PD1, PD2, PD3, and PD4 of each pixel region PX.

A lens insulating layer 322 may be formed on the color filter 320, and a microlens 330 may be formed on the lens insulating layer 322. The microlens 330 may include a plurality of microlenses 330 (e.g., microlenses 3301 and 3303), and the plurality of microlenses 330 may be respectively disposed on a plurality of pixel regions PX. A plurality of microlenses 330 may vertically (e.g., in the third direction D3) overlap the first to fourth photoelectric conversion regions PD1, PD2, PD3, and PD4 of each pixel region PX.

As another example, one microlens 330 may be provided to correspond to a plurality of photoelectric conversion regions PD1, PD2, PD3, and PD4. In one embodiment, one microlens 330 may be commonly provided on the first to fourth photoelectric conversion regions PD1, PD2, PD3, and PD4. The first to fourth photoelectric conversion regions PD1, PD2, PD3, and PD4 may define one pixel region PX. One color filter 320 may be provided to correspond to a plurality of photoelectric conversion regions PD1, PD2, PD3, and PD4.

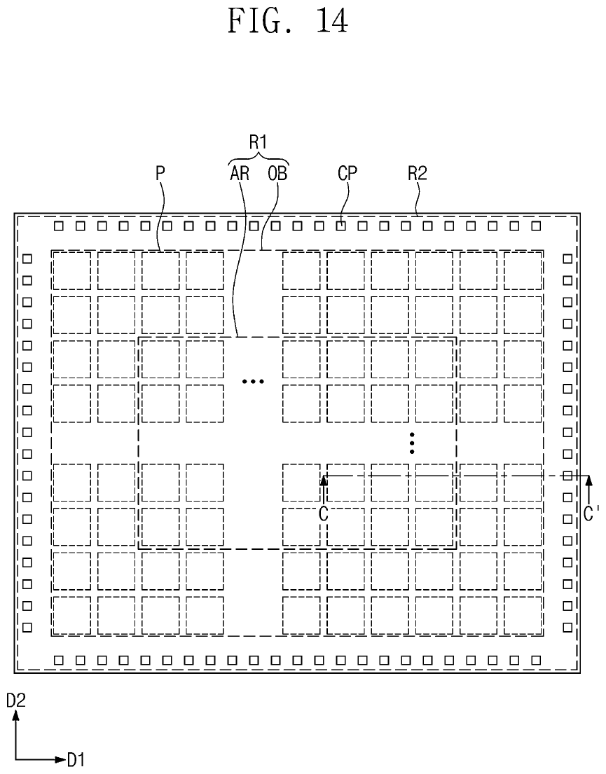

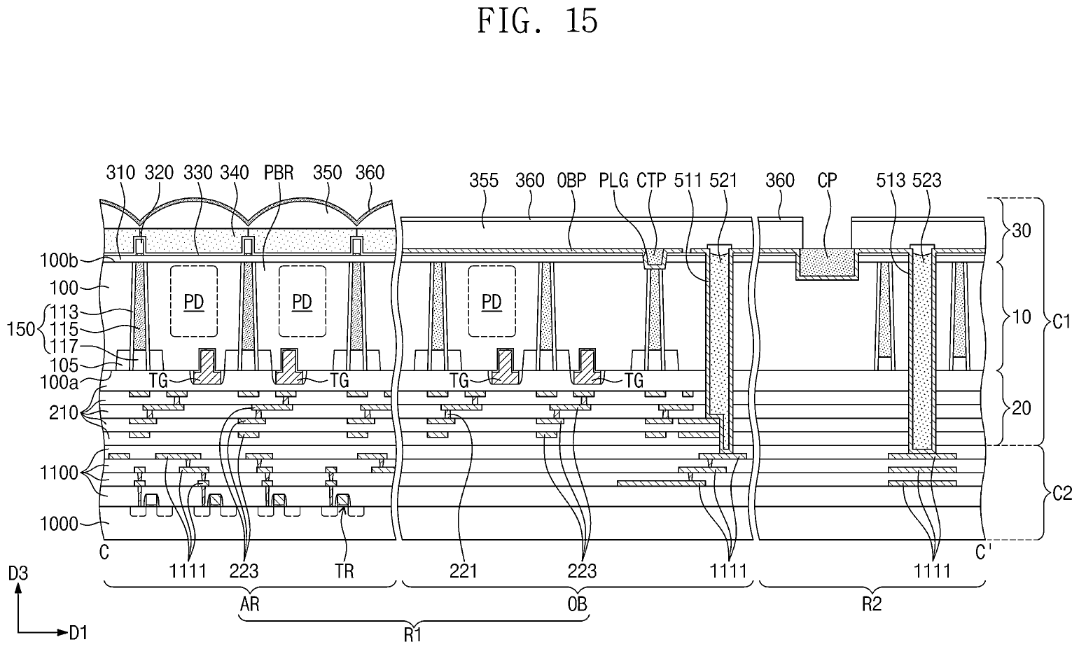

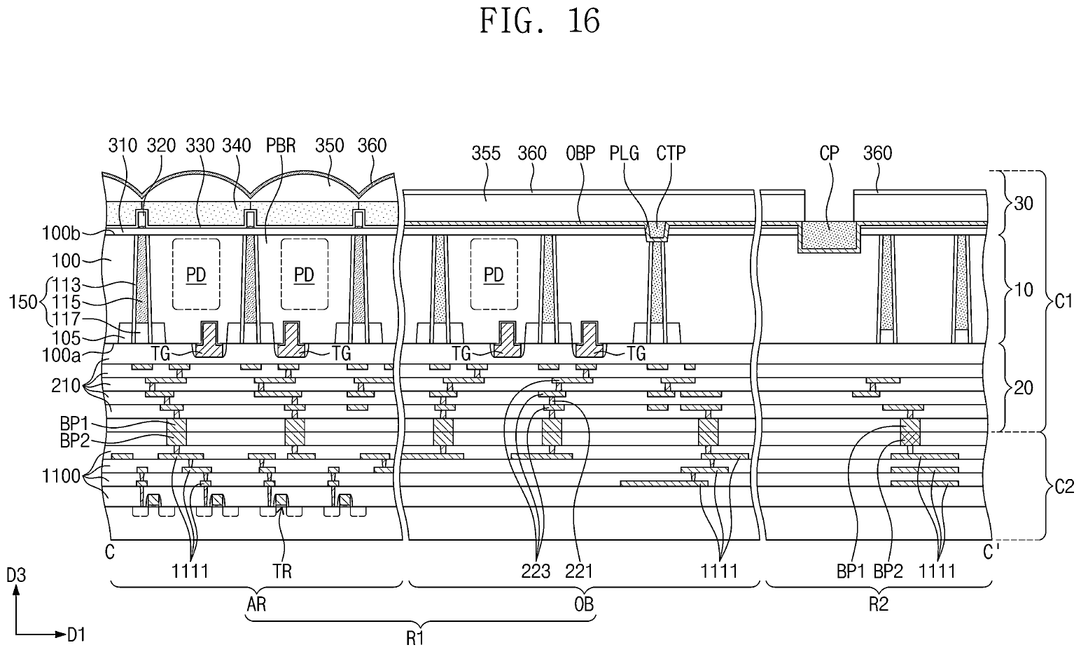

FIG. 14 is a schematic plan view of an image sensor including a semiconductor device according to embodiments of the inventive concept. FIGS. 15 and 16 are cross-sectional views of an image sensor according to embodiments of the inventive concept, taken along line C-C′ of FIG. 13.

Referring to FIGS. 14 and 15, an image sensor may include a sensor chip C1 and a logic chip C2. The sensor chip C1 may include a pixel array region R1 and a pad region R2.

The pixel array region R1 may include a plurality of unit pixels P arranged two-dimensionally in the first and second directions D1 and D2 that intersect each other. Each of the unit pixels P may include a photoelectric conversion element and a readout element. An electrical signal generated by incident light may be output from each of the unit pixels P of the pixel array region R1.

The pixel array region R1 may include a light receiving region AR and a light blocking region OB. The light blocking region OB may surround the light receiving region AR when viewed in a two-dimensional perspective view. In other words, the light blocking region OB may be arranged above, below, and to the left and right of the light receiving region AR when viewed in a planar perspective view. Reference pixels on which light is not incident may be provided in the light blocking region OB, and the amount of charge sensed by unit pixels P in the light receiving region AR may be compared with the reference amount of charge generated in the reference pixels P, and thus the amount of the electrical signal detected in unit pixels P may be calculated.

A plurality of conductive pads CP used to input and output control signals, and photoelectric signals may be disposed in the pad region R2. The pad region R2 may surround the pixel array region R1 when viewed in a plan view to facilitate electrical connection with external devices. The conductive pads CP may input and output electrical signals generated from the unit pixels P to an external device.

The sensor chip C1 in the light receiving region AR may include the same technical features as the image sensor described above. That is, as described above, the sensor chip C1 may include the photoelectric conversion layer 10 between the readout circuit layer 20 and the light transmission layer 30 in the vertical direction. As described above, the photoelectric conversion layer 10 of the sensor chip C1 may include a substrate 100, a separation structure defining pixel regions, and photoelectric conversion regions PD provided in the pixel regions. The separation structure 150 may have substantially the same structure in the light receiving region and the light blocking region OB.

The light transmission layer 30 may include a light blocking pattern OBP, a backside contact plug PLG, a contact pattern CTP, an organic layer 355, and a passivation layer 360 in the light blocking region OB.

A portion of the separation structure 150 may be connected to the backside contact plug PLG in the light blocking region OB.

In detail, the semiconductor pattern 115 may be connected to the backside contact plug PLG in the light blocking region OB. A negative bias may be applied to the semiconductor pattern 115 through the contact pattern CTP and the backside contact plug PLG. Accordingly, dark current occurring at a boundary between the separation structure 150 and the substrate 100 may be reduced.

The backside contact plug PLG may have a width greater than a width of the separation structure 150. The backside contact plug PLG may include metal and/or metal nitride. For example, the backside contact plug PLG may include titanium and/or titanium nitride.

The contact pattern CTP may be buried in a contact hole where the backside contact plug PLG is formed. The contact pattern CTP may include a different material than the backside contact plug PLG. For example, the contact pattern CTP may include aluminum (Al).

The contact pattern CTP may be electrically connected to the semiconductor pattern 115 of the separation structure 150. A negative bias may be applied to the semiconductor pattern 115 of the separation structure 150 through the contact pattern CTP, and the negative bias may be transferred from the light blocking region OB to the light receiving region AR.

In the light blocking region OB, the light blocking pattern OBP may continuously extend from the backside contact plug PLG and be disposed on an upper surface of the flat insulating layer 310. That is, the light blocking pattern OBP may include the same material as the backside contact plug PLG. The light blocking pattern OBP may include metal and/or metal nitride. For example, the light blocking pattern OBP may include titanium and/or titanium nitride. The light blocking pattern OBP may not extend to the light receiving region AR of the pixel array.

The light blocking pattern OBP may block light from being incident on the photoelectric conversion regions PD provided in the light blocking region OB. The photoelectric conversion regions PD in the reference pixel regions of the light blocking region OB may not output a photoelectric signal but may output a noise signal. The noise signal may be generated by electrons generated by heat generation or dark current.

An organic layer 355 and a passivation layer 360 may be provided on the light blocking pattern OBP in the edge region ER. The organic layer 355 may include the same material as the microlenses 350.

In the light blocking region OB, a first penetration conductive pattern 511 may penetrate the substrate 100 and may be electrically connected to the metal wirings 223 of the readout circuit layer 20 and the wiring structure 1111 of the logic chip C2. The first penetration conductive pattern 511 may have a first bottom surface and a second bottom surface positioned at different levels. A first buried pattern 521 may be provided inside the first penetration conductive pattern 511. The first buried pattern 521 may include a low refractive index material and may have insulating properties.

In the pad region R2, conductive pads CP may be provided on the second surface 100b of the substrate 100. The conductive pads CP may be buried in the second surface 100b of the substrate 100. As an example, the conductive pads CP may be provided in a pad trench formed on the second surface 100b of the substrate 100 in the pad region R2. The conductive pads CP may include metal such as aluminum, copper, tungsten, titanium, tantalum, or alloys thereof. In the image sensor mounting process, a bonding wire may be bonded to the conductive pads CP. The conductive pads CP may be electrically connected to an external device through the bonding wire.

In the pad region R2, a second penetration conductive pattern 513 may penetrate the substrate 100 and be electrically connected to the wiring structure 1111 of the logic chip C2. The second penetration conductive pattern 513 may extend onto the second surface 100b of the substrate 100 and be electrically connected to the conductive pads CP. A portion of the second penetration conductive pattern 513 may cover a bottom surface and sidewalls of the conductive pads CP. A second buried pattern 523 may be provided inside the second penetration conductive pattern 513. The second buried pattern 523 may include a low refractive index material and may have insulating properties. In the pad region R2, separation structures 150 may be provided around the second penetration conductive pattern 513.

The logic chip C2 may include a logic semiconductor substrate 1000, logic circuits TR, interconnection structures 1111 connected to the logic circuits, and logic interlayer insulating layers 1100. The uppermost layer of the logic interlayer insulating layers 1100 may be bonded to the readout circuit layer 20 of the sensor chip C1. The logic chip C2 may be electrically connected to the sensor chip C1 through the first penetration conductive pattern 511 and the second penetration conductive pattern 513.

In one example, the sensor chip C1 and the logic chip C2 are described as being electrically connected to each other through first and second penetration conductive patterns 511 and 513, but the inventive concept is not limited thereto.

Referring to FIG. 16, the first and second penetration conductive patterns 511 and 513 of FIG. 15 may be omitted, and bonding pads provided on the uppermost metal layer of the sensor chip C1 and the logic chip C2 may be directly bonded to each other, and thus the sensor chip C1 and the logic chip C2 may be electrically connected.

In detail, the sensor chip C1 of the image sensor may include first bonding pads BP1 provided on the uppermost metal layer of the readout circuit layer 20, and the logic chip C2 may include second bonding pads BP2 provided on the uppermost metal layer of the wiring structure 1111. The first and second bonding pads BP1 and BP2 may include at least one of, for example, tungsten (W), aluminum (Al), copper (Cu), tungsten nitride (WN), tantalum nitride (TaN), and titanium nitride (TiN).

The first bonding pads BP1 of the sensor chip C1 and the second bonding pads BP2 of the logic chip C2 may be directly electrically connected to each other using a hybrid bonding manner. The hybrid bonding refers to bonding in which two components containing the same type of material fuse at their interface. For example, when the first and second bonding pads BP1 and BP2 are formed of copper (Cu), the first and second bonding pads BP1 and BP2 may be physically and electrically connected by copper (Cu)-copper (Cu) bonding. Additionally, a surface of the insulating layer of the sensor chip C1 and a surface of the insulating layer of the logic chip C2 may be bonded by dielectric-dielectric bonding.

According to aspects of the inventive concept, the thickness of the source follower gate insulating layer interposed between the source follower gate electrode and the substrate may increase as the source follower gate insulating layer approaches the device isolation pattern. In this case, the channel region formed under the source follower gate insulating layer may be formed to be spaced apart from the device isolation pattern. As a result, the width of the channel region through which current flows may be increased, and the reduction of noise may be improved. As a result, the electrical characteristics of the image sensor may be further improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. An image sensor comprising:
a substrate including a first pixel region;
a separation structure provided in the substrate to define the first pixel region; and
a source follower transistor on the first pixel region,
wherein the source follower transistor includes a source follower gate electrode and a first gate insulating layer interposed between the source follower gate electrode and the substrate,
wherein the source follower gate electrode extends in a first direction and is disposed between a device isolation pattern and the separation structure,
wherein the first gate insulating layer includes:
a first portion adjacent to the device isolation pattern, including a first sidewall adjacent to the device isolation pattern; and
a second portion adjacent to the separation structure,
wherein the first portion has a first thickness in a vertical direction, and
wherein the first thickness decreases as a distance from the first sidewall increases in the first direction.

2. The image sensor of claim 1, wherein the first portion includes a first upper surface in contact with the source follower gate electrode, and
wherein the first upper surface has an inclined profile.

3. The image sensor of claim 1, further comprising a second pixel region adjacent to the first pixel region,
wherein the second pixel region includes a second gate insulating layer and a first gate electrode on the second gate insulating layer, and
wherein the second gate insulating layer has a thickness smaller the first thickness.

4. The image sensor of claim 1, wherein the first thickness has a maximum value at the first sidewall.

5. The image sensor of claim 1, wherein a first active region and a second active region are defined by the device isolation pattern,
wherein the first and second active regions are spaced apart from each other in the first direction,
wherein the first active region is adjacent to a floating diffusion region, and
wherein the second active region is adjacent to the separation structure.

6. The image sensor of claim 5, further comprising a channel region on an upper portion of the second active region,
wherein the channel region is formed below the second portion, and
wherein the channel region is spaced apart from the device isolation pattern in the first direction.

7. The image sensor of claim 5, wherein the first active region further includes a transfer gate electrode and a transfer gate insulating layer interposed between the transfer gate electrode and the first active region, and
wherein the transfer gate insulating layer has a thickness smaller than the first thickness.

8. The image sensor of claim 5, further comprising a first source/drain pattern and a second source/drain pattern on the second active region,
wherein the source follower gate electrode is disposed between the first source/drain pattern and the second source/drain pattern.

9. The image sensor of claim 1, wherein the first portion includes a first edge portion, a second edge portion spaced apart from the first edge portion in a second direction intersecting the first direction, and a central portion between the first edge portion and the second edge portion, and
wherein the first edge portion has a thickness greater than that of the central portion, and the second edge portion has a thickness greater than that of the central portion.

10. The image sensor of claim 1, wherein a pixel group includes a plurality of the pixel regions,
wherein a floating diffusion region is disposed at a center of the pixel group, and
wherein the pixel regions share the floating diffusion region.

11. An image sensor comprising:
a substrate including a first pixel region; and
a source follower transistor on the first pixel region,
wherein the source follower transistor includes a first source/drain pattern, a second source/drain pattern, a source follower gate electrode, and a source follower gate insulating layer interposed between the source follower gate electrode and the substrate,
wherein the source follower gate electrode is interposed between the first source/drain pattern and the second source/drain pattern and extends in a first direction,
wherein the source follower gate insulating layer includes:
a first edge portion adjacent to the first source/drain pattern;
a second edge portion spaced apart from the first edge portion in a second direction, the second direction intersecting the first direction; and
a central portion interposed between the first edge portion and the second edge portion, and
wherein the first edge portion has a thickness greater than that of the central portion, and the second edge portion has a thickness greater than that of the central portion.

12. The image sensor of claim 11, wherein a contact surface in contact with the source follower gate insulating layer and the source follower gate electrode includes a portion having an inclined profile.

13. The image sensor of claim 11, wherein the first pixel region further includes a transfer gate electrode and a transfer gate insulating layer interposed between the transfer gate electrode and the substrate, and
wherein the transfer gate insulating layer has a thickness smaller than the thickness of the first edge portion and the second edge portion.

14. The image sensor of claim 11, wherein the source follower gate electrode is disposed between a device isolation pattern and a separation structure.

15. The image sensor of claim 14, further comprising a channel region below the source follower gate insulating layer,
wherein the channel region is spaced apart from the device isolation pattern.

16. The image sensor of claim 11, further comprising a second pixel region adjacent to the first pixel region,
wherein the second pixel region includes a first gate insulating layer and a first gate electrode on the first gate insulating layer, and
wherein a thickness of the first gate insulating layer is smaller than the thickness of the first edge portion and the thickness of the second edge portion.

17. An image sensor comprising:
a substrate including a pixel region, the substrate having first and second surfaces facing each other;
a separation structure provided in the substrate to define the pixel region;
a photoelectric conversion region provided in the substrate in the pixel region;
a floating diffusion region provided in the substrate and spaced apart from the photoelectric conversion region in the pixel region;
a device isolation pattern extending from the first surface into the substrate and defining a first active region and a second active region on the pixel region, the first active region being adjacent to the floating diffusion region, the second active region being adjacent to the separation structure;
a transfer gate electrode disposed on the first surface in the first active region and extending into the substrate;
a source follower gate electrode disposed on the first surface in the second active region;
a source follower gate insulating layer disposed between the source follower gate electrode and the first surface;
a first source/drain pattern provided in the substrate in the pixel region at one side of the source follower gate electrode;
a second source/drain pattern provided in the substrate in the pixel region on the other side of the source follower gate electrode;
a gate insulating layer between the source follower gate electrode and the substrate;
a microlens on the second surface, the microlens overlapping the photoelectric conversion region; and
a wiring layer disposed on the first surface,
wherein the source follower gate electrode is provided between the device isolation pattern and the separation structure and extends in a first direction,
wherein the source follower gate insulating layer includes:
a first portion adjacent to the device isolation pattern, the first portion including a first sidewall adjacent to the device isolation pattern; and
a second portion adjacent to the separation structure,
wherein the first portion has a first thickness in a vertical direction, and
wherein the first thickness decreases as a distance from the first sidewall increases in the first direction.

18. The image sensor of claim 17, wherein a pixel group includes a plurality of the pixel regions,
wherein the floating diffusion region is disposed at a center of the pixel group, and
wherein the pixel regions share the floating diffusion region.

19. The image sensor of claim 17, further comprising a transfer gate insulating layer between the transfer gate electrode and the substrate,
wherein a thickness of the transfer gate insulating layer is smaller than the first thickness.

20. The image sensor of claim 17, wherein the first thickness has a maximum value at the first sidewall.
